(19) United States
(12) Patent Application Publication
(10) Pub. No.: US 2008/0096294 A1
(43) Pub. Date: Apr. 24, 2008

(54) INTEGRATED CIRCUIT STRUCTURE, DISPLAY MODULE, AND INSPECTION METHOD THEREOF

(76) Inventors: Yao-Ren Liu, Hsin-Chu (TW); Qing He, Hsin-Chu (TW)

Correspondence Address: NORTH AMERICA INTELLECTUAL PROPERTY CORPORATION, P.O. BOX 506, MERRIFIELD, VA, 22116, US

(21) Appl. No.: 11/685,149

(22) Filed: Mar. 12, 2007

(30) Foreign Application Priority Data
Oct. 24, 2006 (TW) 095139112

(51) Int. Cl. H01L 21/66; H01L 23/482; H01L 33/00

(52) U.S. Cl. 438/16; 257/737; 257/99; 438/17; 257/E23.021; 257/E21.525; 257/E33.066

(57) ABSTRACT

An integrated circuit structure has an IC chip, at least a functional bump, and at least a dummy bump positioned on a joint surface of the IC chip. A terminal surface of the dummy bump is different in appearance from a terminal surface of the functional bump, which improves an inspection process during production of the IC chip.

### BACKGROUND IF THE INVENTION

1. Field of the Invention

The present invention relates to an integrated circuit (IC) structure, and more particularly, to an IC structure comprising a differentiable dummy bump positioned on the IC structure.

2. Description of the Prior Art

Due to the fast development of display technology, the flat display panel module is used widely in digital cameras, personal digital assistants, cell phones, and flat display TVs, and especially in liquid crystal display (LCD) panels and OLED display panels. A normal flat display panel module, be it an LCD panel or an OLED display panel, usually includes a top substrate and a bottom substrate, such as a glass substrate. Usually, a pixel array region and a periphery region are defined on the bottom substrate, where the bottom substrate further comprises a plurality of conducting pads positioned on the periphery region. The conducting pads correspond to functional bumps on driver IC chips in order to connect to external circuits.

FIG. 1 is a top view of a conventional flat display panel module 10. The flat display panel module 10 is an LCD panel comprising two substrates 12, 14 and a liquid crystal layer (not shown) positioned between the two substrates 12, 14. In general, substrates of LCD panels are made of glass, organic glass, such as Acrylics, or other transparent materials. Glass is a better material for LCD panels. As shown in FIG. 1, the top glass substrate 12 is smaller than the bottom glass substrate 14. Therefore, an area of the bottom glass substrate 14 covered by the top glass substrate 12 is defined as a covered region, and another portion of the bottom glass substrate 14 is an uncovered region defined as a periphery region. The covered region includes a pixel array region (shown in dotted lines) connected to the periphery region through wires 18, such as signal lines or scan lines. There are a plurality of periphery circuits and conducting pads electrically connected to the outside circuits (not shown) by the functional bumps on the driver IC chip 20, so as to control the flat display panel module 10 to display images.

FIG. 2 shows an outer drawing of the conventional IC structure 20 shown in FIG. 1. The conventional IC structure 20 comprises an IC chip 30, and the IC chip 30 has a joint surface 26, which includes a plurality of bumps 28 formed thereon. There are two kinds of bumps: functional bumps 22, and dummy bumps 24. The dummy bumps 24 are filled in for purposes of illustration in FIG. 2, but the functional bumps 22 and the dummy bumps 24 cannot be distinguished by their appearance in practice. The functional bumps 22 are used to make electrical connections between the IC structure 20 and the conducting pads 24 to send signals; the dummy bumps 24 are used to balance the pressure on the IC structure 20, but do not provide any electrical function. Therefore, even if some of the dummy bumps 24 have defects, the IC structure 20 is still functional and reliable, and the flat display panel module 10 is still operative. However, as shown in FIG. 2, because the functional bumps 22 and the dummy bumps 24 are identical in the appearance of their respective terminal surfaces, it is hard to distinguish them. By inspecting the bumps on the IC structure 20 during a production process, defects on the bumps can be found, and the bumps with the defects can be identified as ineffective bumps. However, it is difficult to decide whether the ineffective bumps are the functional bumps 22 or the dummy bumps 24, since they look the same. The identical terminal surface of the functional and dummy bumps make it possible for an effective IC structure 20 to be identified incorrectly as an ineffective one due to the defective dummy bump. The replacement of the IC structure (which is actually functional) causes waste in time and human resources.

As mentioned above, because of the identical terminal surfaces of the functional and dummy bumps, it is hard to distinguish whether the ineffective bumps are the functional bumps or the dummy bumps on the production line. Erroneous judgment may easily occur and the production cost will increase.

### SUMMARY OF THE INVENTION

It is therefore an objective of the present invention to provide a dummy bump, which can be distinguished from a functional bump during an inspection process to solve the above-mentioned problem.

According to the present invention, an IC structure is provided. The IC structure comprises an IC chip having a joint surface, at least a functional bump positioned on the joint surface and at least a dummy bump positioned on the joint surface, and the terminal surface of the dummy bump is different from the terminal surface of the functional bump.

According to the present invention, a method of inspecting an IC chip is also provided. The IC chip comprising a plurality of functional bumps and at least a dummy bump, the functional bumps and the dummy bump are positioned on a joint surface of the IC chip, and the terminal surface of the dummy bump is different from the terminal surface of the functional bumps. The method comprises inspecting the joint surface to detect if there is any ineffective bump, and identifying ineffective bump to decide the bump is either the dummy bump or one of the functional bumps.

It is advantageous that the functional bumps and the dummy bumps are different in their terminal surface, hence we can distinguish the ineffective bumps are either the functional bumps or the dummy bumps efficaciously.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a top view of a conventional display module.

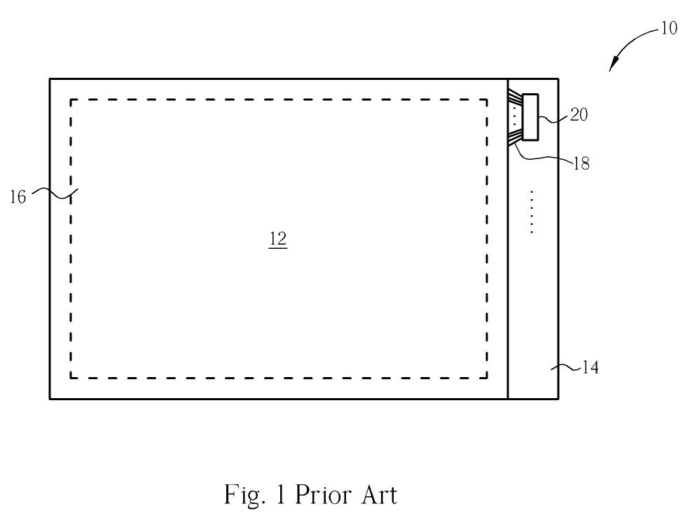

FIG. 2 illustrates an outer drawing of a conventional IC structure of FIG. 1.

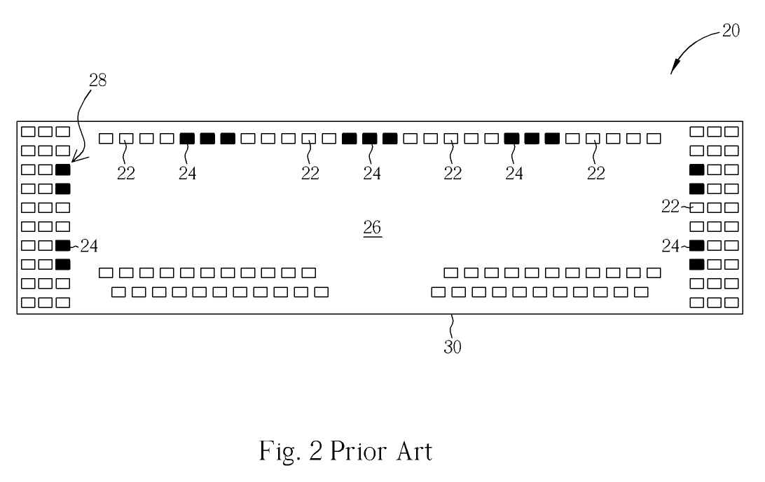

FIG. 3 illustrates a top view of a display module according to the present invention.

FIG. 4 illustrates an enlarged view of a periphery region of the display module in FIG. 3.

FIG. 5 illustrates an enlarged view of an IC structure according to the present invention.

FIG. 6 illustrates a terminal surface of a dummy bump in accordance with the embodiments of this invention.

FIG. 7 illustrates an exterior of the IC structure in accordance with the preferred embodiment of this invention.

FIG. 8 illustrates a flowchart of a method for inspecting an IC chip, according to the present invention.

FIG. 9 illustrates a flowchart of a method for inspecting the display module, according to the present invention.

### DETAILED DESCRIPTION

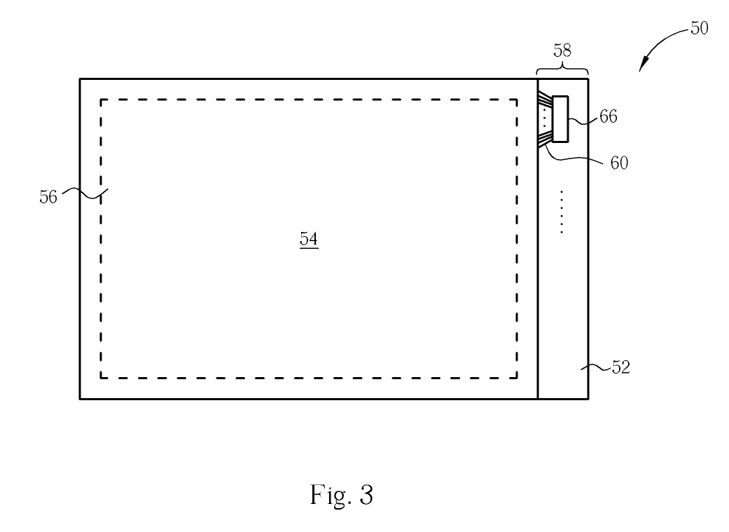

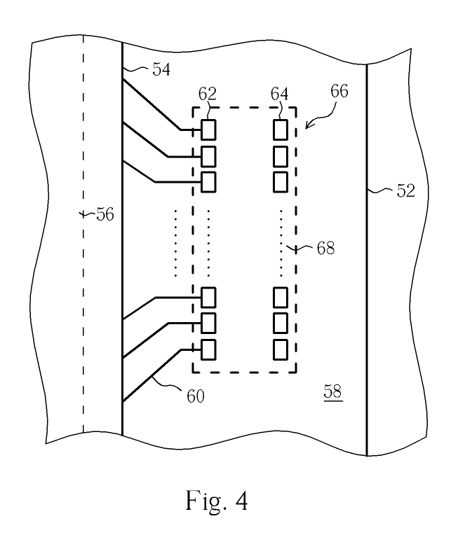

Referring to FIG. 3 and FIG. 4, FIG. 3 depicts a top view of a display module 50, and FIG. 4 is an enlarged view of a periphery region of the display module 50. The display module 50 of the present invention is an LCD panel. The display module 50 comprises a bottom substrate 52, a top substrate 54 and a liquid crystal layer (not shown) between the two substrates. An area of the bottom substrate 52 covered by the top substrate 54 is defined as a pixel array region 56 and an uncovered region is defined as a periphery region 58. A plurality of periphery circuits 60 and a plurality of conducting pads 62, 64 are located in the periphery region 58. Moreover, a plurality of IC structures is positioned in the periphery region 58, which electrically connects the conducting pads 62, 64 through the functional bumps to the contact region.

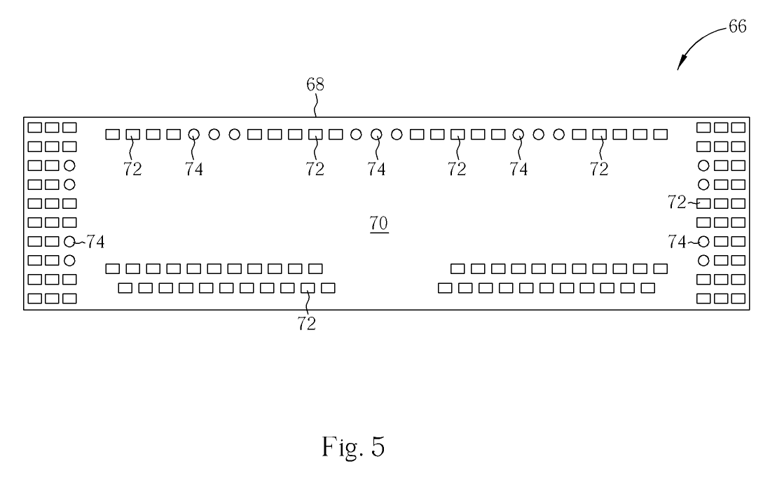

With reference to FIG. 5, it is an enlarged view of the IC structure 66 according to the present invention. The IC structure 66 comprises an IC chip 68, and the IC chip 68 has a joint surface 70, which is the contact surface between the IC chip 68 and the bottom substrate 52. The IC structure 66 further comprises a plurality of functional bumps 72 connected to the corresponding conducting pads 62, 64 on the bottom substrate 52, and the IC structure 66 also comprises a plurality of dummy bumps 74. The functional bumps 72 and the dummy bumps 74 are positioned on the surface of the joint surface 70, and the terminal surface of the dummy bumps 74 is different from the terminal surface of the functional bumps 72. The “terminal surface” mentioned above refers to an outer contact surface between the dummy bumps 74 and the conducting pads 62, 64, and an outer contact surface between the functional bumps 72 and the bottom substrate 52. In the present invention, “the terminal surface is different” means that the respective terminal surfaces of the dummy bumps 74 and the functional bumps 72 can be distinguished by size, shape or surface area by means of a microscope or other tools, or by auto optical inspection (AOI), for example. As shown in FIG. 5, the terminal surfaces of the functional bumps 72 are rectangular, and the terminal surfaces of the dummy bumps are circular. Therefore, the difference in appearance of the dummy bumps 74 and the functional bumps 72 is clear.

In addition, the main function of the dummy bumps 74 is to balance the pressure on the IC structure 68. In general, the dummy bumps 74 and the functional bumps 72 are placed alternately. As shown in FIG. 5, the dummy bumps 74 and the functional bumps 72 are located collinearly on the joint surface 70. Some of the dummy bumps 74 are adjacent to each other and are between two of the functional bumps 72. On the other hand, the dummy bumps 74 and the functional bumps 72 located on the left and right sides of the IC structure 68 are collinearly arranged, as pluralities of vertically lines. The dumpy bumps 74 are also positioned between two of the functional bumps 72.

Although the dummy bumps 74 and the functional bumps 72 are placed on the joint surface 70 alternately and mixed, production workers can still distinguish between them due to the different shapes of the terminal surfaces of the dummy bumps 74 and the functional bumps 72. In the product examination, if there are defects on the bumps, production workers can determine rapidly if the bumps with defects are the dummy bumps 74 or the functional bumps 72. If only the dummy bumps are broken, the IC structure 66 is still qualified and does not need to be replaced.

According to the principle of the present invention, the terminal surfaces of the dummy bumps 74 can be elliptical or have a non-rectangular polygonal shape in order to look different from the functional bumps 72.

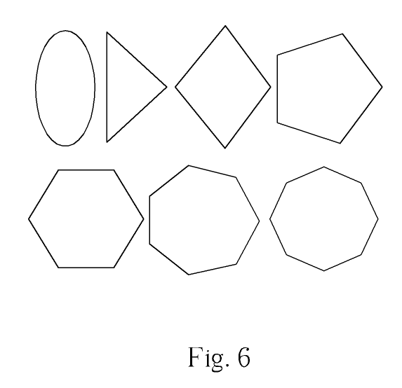

Referring to FIG. 6, it shows several possible shapes of terminal surfaces of the dummy bumps 74 in various embodiments of the present invention, including an ellipse, a triangle, a diamond, a pentagon, a hexagon, a heptagon and an octagon, etc. Moreover, in other embodiments of the present invention, the shapes of the terminal surfaces of the dummy bumps 74 and the functional bumps 72 are exchangeable. For example, the terminal surfaces of the functional bumps 72 can be an ellipse or a circle, while the terminal surface of the dummy bumps 74 is a polygon. In addition, the terminal surfaces of the dummy bumps 74 and the functional bumps 72 can be similar and only differ in their sizes. As long as the dummy bumps 74 and the functional bumps 72 of the IC structure 66 can be distinguished by their appearance, it's included in the scope of the present invention.

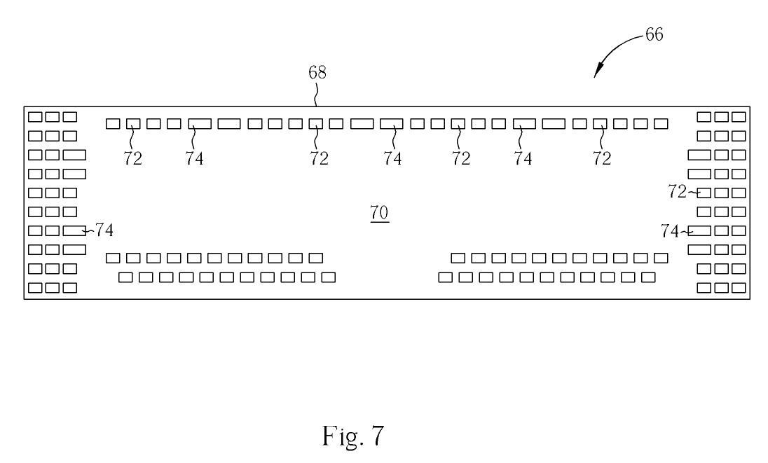

With reference to FIG. 7, it shows an exterior of an IC structure in another embodiment of the present invention. The numerals of elements in FIG. 7 are the same as those in FIG. 5 for simplifying the explanation. In this embodiment, the terminal surface of the functional bumps 72 is a first rectangle and the terminal surface of the dummy bumps 74 is a second rectangle. As shown in FIG. 7, the first rectangle and the second rectangle are different in their side ratio and the area of the terminal surface of the functional bumps 72 is different from the area of the terminal surfaces of the dummy bumps 74, too. Therefore, although the terminal surfaces of the functional bumps and the dummy bumps are both rectangles, production workers can still distinguish them by the area or the shape of the terminal surfaces and the ineffective dummy bumps will not be identified as ineffective functional bumps. The waste of material can be avoided.

As mentioned above, because the functional bumps and the dummy bumps on the IC structure comprise different shapes or areas of the terminal surfaces, it will be easy to determine whether the ineffective bumps are the functional bumps or not.

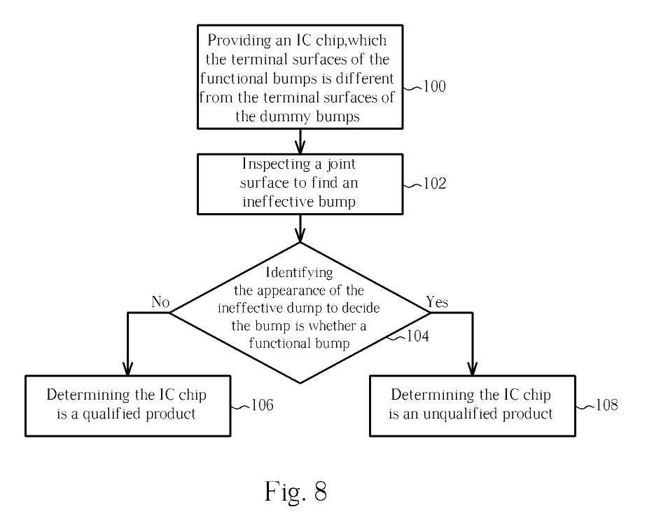

FIG. 8 shows a flowchart of a method for inspecting the IC chip, according to the present invention. The steps comprise:

Step 100: providing an IC chip comprising a plurality of functional bumps and at least a dummy bump positioned on a joint surface of the IC chip, the terminal surface of the dummy bump being different from any terminal surface of the functional bumps;

Step 102: inspecting the joint surface to find an ineffective bump;

Step 104: identifying an appearance of the ineffective bump to determine if the ineffective bump is the dummy bump or one of the functional bumps; if the ineffective bump is the dummy bump then go to Step 106; if the ineffective bump is one of the functional bumps, than go to Step 108;

Step 106: determining that the IC chip is a qualified product and continuing on to next processes;

Step 108: determining that the IC chip is an unqualified product, and discarding it, reworking it, or reproducing it.

The inspections in Step 102 and/or Step 104 can be an auto optical inspection (AOI), manual visual inspection or other similar inspection processes.

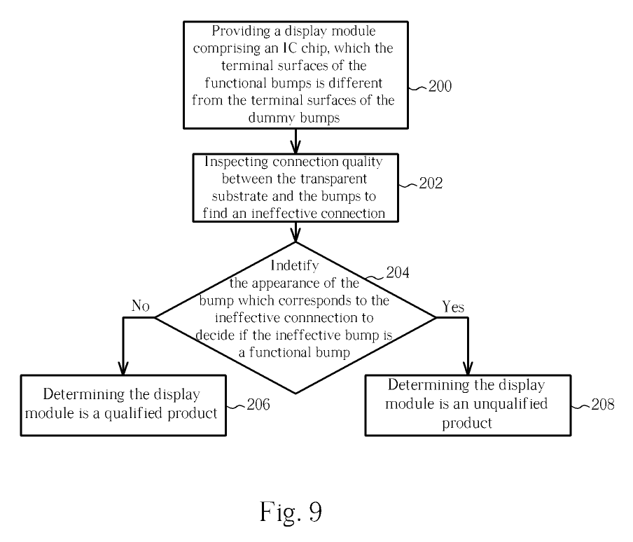

With reference to FIG. 9, it shows a flowchart of a method for inspecting the display module, according to the present invention, the steps comprising:

Step 200: providing a substrate and an integrated circuit structure, the substrate comprising at least a conducting pad, the integrated circuit structure comprising an integrated circuit chip with a joint surface, at least a functional bump and at least a dummy bump positioned on the joint surface of the integrated circuit chip, and the terminal surface of the dummy bump having a different appearance from the terminal surface of the functional bump;

Step 202: inspecting connection quality between the substrate and the functional bump or between the substrate and the dummy bump to detect an ineffective connection and thereby identify an ineffective bump;

Step 204: identifying the appearance of the bump corresponding to the ineffective connection to decide if the ineffective bump is the dummy bump or the functional bump; if the ineffective bump is the dummy bump, then go to Step 206; if the ineffective bump is the functional bump, then go to Step 208;

Step 206: determining that the display module is a qualified product;

Step 208: determining that the display module is an unqualified product.

When identifying the appearance of the bumps in Step 204, if the substrate is transparent, production workers can see through the substrate to determine the shapes of the bumps. Some conduction pads on the substrate may be coated with metal, thus they are not transparent. However, the production workers can still identify the shape of the terminal surface by the imprint on the metal layer to determine if the ineffective bump is a dummy bump or a functional bump. For an opaque substrate, an X-ray inspection may be used to identify the terminal surface or shape of the ineffective bump.

In comparison with the prior art, the different appearances of the terminal surfaces of the dummy bumps and the functional bumps make it easy for the production workers to determine whether the ineffective bumps are the functional bumps or not, and erroneous determination of the qualified product as the unqualified product can be avoided such that unneeded waste of materials and manpower is avoided. Accordingly, the process cost can be reduced and the yield is effectively raised. It is noteworthy that the IC structure can be applied to different display modules, for example LCD panels, OLED display panels, or other electrical devices with IC structures or IC chips.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit (IC) structure comprising:
an integrated circuit chip having a joint surface;
at least a functional bump positioned on the joint surface; and
at least a dummy bump positioned on the joint surface;
wherein a terminal surface of the dummy bump is different from a terminal surface of the functional bump.

2. The integrated circuit structure of claim 1, wherein an area of the terminal surface of the dummy bump is different from an area of the terminal surface of the functional bump.

3. The integrated circuit structure of claim 1, wherein a shape of the terminal surface of the dummy bump is different from a shape of the terminal surface of the functional bump.

4. The integrated circuit structure of claim 1, wherein a shape of the terminal surface of the functional bump is rectangular, and a shape of the terminal surface of the dummy bump is circular, elliptical, or a non-rectangular polygonal shape.

5. The integrated circuit structure of claim 1, wherein the terminal surface of the functional bump is a first rectangle, the terminal surface of the dummy bump is a second rectangle, and the first rectangle and the second rectangle have different side ratios.

6. The integrated circuit structure of claim 1, wherein a shape of the terminal surface of the functional bump is circular or elliptical, and a shape of the terminal surface of the dummy bump is polygonal.

7. A display module comprising:
a substrate having at least a conducting pad; and
an integrated circuit structure comprising:
an integrated circuit chip having a joint surface;
at least a functional bump positioned on the joint surface; and
at least a dummy bump positioned on the joint surface;
wherein a terminal surface of the dummy bump is different from a terminal surface of the functional bump, and the functional bump contacts the conducting pad.

8. The display module of claim 7, wherein an area of the terminal surface of the dummy bump is different from an area of the terminal surface of the functional bump.

9. The display module of claim 7, wherein a shape of the terminal surface of the dummy bump is different from a shape of the terminal surface of the functional bump.

10. The display module of claim 7, wherein the shape of the terminal surface of the functional bump is rectangular, and the shape of the terminal surface of the dummy bump is circular, elliptical, or a non-rectangular polygonal shape.

11. The display module of claim 7, wherein the terminal surface of the functional bump is a first rectangle, the terminal surface of the dummy bump is a second rectangle, and the first rectangle and the second rectangle have different side ratios.

12. The display module of claim 7, wherein the shape of the terminal surface of the functional bump is circular or elliptical, and the shape of the terminal surface of the dummy bump is polygonal.

13. The display module of claim 7, wherein the substrate is a transparent substrate.

14. The display module of claim 13, wherein the transparent substrate is a glass substrate.

15. A method for inspecting an integrated circuit chip comprising a plurality of functional bumps and at least a dummy bump positioned on a joint surface of the integrated circuit chip, the terminal surface of the dummy bump being different from any terminal surface of the functional bumps, the method comprising:
inspecting the joint surface to detect an ineffective bump; and
identifying an appearance of the ineffective bump to decide if the ineffective bump is either the dummy bump or one of the functional bumps.

16. The method of claim 15, wherein identifying the appearance of the ineffective bump comprises:
determining that the integrated circuit chip is a qualified product if the ineffective bump is the dummy bump;
determining that the integrated circuit chip is an unqualified product if the ineffective bump is one of the functional bumps.

17. A method for inspecting a display module comprising a substrate and an integrated circuit structure having at least a conducting pad, an integrated circuit chip with a joint surface, at least a functional bump and at least a dummy bump positioned on the joint surface of the integrated circuit chip, a terminal surface of the dummy bump being different from a terminal surface of the functional bump, the method comprising:
inspecting connection quality between the substrate and the functional bump or between the substrate and the dummy bump to detect an ineffective connection; and
identifying the appearance of the bump corresponding to the ineffective connection to decide if the ineffective bump is either the dummy bump or the functional bump.

18. The method of claim 17, wherein identifying the appearance of the bump corresponding to the ineffective connection comprises:
determining that the display module is a qualified product if the ineffective bump is the dummy bump;
determining that the display module is an unqualified product if the ineffective bump is the functional bump.
